(19) United States
(12) Patent Application Publication
(10) Pub. No.: US 2025/0286519 A1
(43) Pub. Date: Sep. 11, 2025

(54) PROTECTION LOOP FOR POWER AMPLIFIER

(71) Applicant: Qorvo US, Inc., Greensboro, NC (US)

(72) Inventors: Baker Scott, San Jose, CA (US); Sukchan Kang, San Jose, CA (US); Chong Woo, Fremont, CA (US); George Maxim, Saratoga, CA (US)

(21) Appl. No.: 18/858,196

(22) PCT Filed: Jun. 16, 2023
(86) PCT No.: PCT/US2023/025554

§ 371 Date: Oct. 18, 2024

Related U.S. Application Data
(60) Provisional application No. 63/354,292, filed on Jun. 22, 2022.
(60) Provisional application No. 63/379,516, filed on Oct. 14, 2022.

(51) Int. Cl. H03F 1/52; H03F 3/24; H03F 3/72

(52) U.S. Cl. CPC H03F 1/523; H03F 1/52; H03F 3/245; H03F 3/72; H03F 2200/471; H03F 2203/7206

(57) ABSTRACT

Systems and methods for providing a protection loop for a power amplifier (PA CELL) are disclosed. In one aspect, an over voltage condition is detected (214, 216) at an output of the power amplifier (PA CELL), and a short circuit is selectively created at a base or gate of a transistor within the power amplifier (PA CELL) to debias the transistor and prevent an over voltage condition from damaging the transistor. Provision of such a fast acting over voltage protection option more readily accommodates and protects the power amplifier (PA CELL) in situations with high peak-to-average ratio conditions. This protection may prevent the transistor from being damaged by rapid power fluctuations that may occur, particularly in current cellular standards

### PRIORITY APPLICATIONS

The present application is related to U.S. Provisional Patent Application Ser. No. 63/379,516 filed on Oct. 14, 2022, and entitled “PROTECTION LOOP FOR POWER AMPLIFIER,” the contents of which are incorporated herein by reference in its entirety.

The present application is related to U.S. Provisional Patent Application Ser. No. 63/354,292 filed on Jun. 22, 2022, and entitled “5G POWER AMPLIFIER USING FAST ENGAGE AND RECOVERY DISTRIBUTED DIRECT-BASE SIGNAL LIMITING AND OVP PROTECTION LOOP,” the contents of which are incorporated herein by reference in its entirety.

### BACKGROUND

### I. Field of the Disclosure

The technology of the disclosure relates generally to power amplifiers and, more particularly, to an over voltage protection (OVP) loop for a power amplifier.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been a movement to newer cellular standards to provide greater bandwidth to accommodate all the data being used by these functions. New cellular standards such as the Fifth Generation (5G) have new power level fluctuations, which may put new stresses on power amplifiers associated with a transceiver in the mobile computing device. Such stresses provide room for innovation.

### SUMMARY

Aspects disclosed in the detailed description include systems and methods for providing a protection loop for a power amplifier. In particular, exemplary aspects of the present disclosure detect an over voltage condition at an output of a power amplifier and selectively create a short circuit at a base or gate of a transistor within the power amplifier to debias the transistor and prevent an over voltage condition from damaging the transistor. Provision of such a fast acting over voltage protection option more readily accommodates and protects the power amplifier in situations with high peak-to-average ratio conditions. This protection may prevent the transistor from being damaged by rapid power fluctuations that may occur, particularly in current cellular standards.

In this regard, in one aspect, a power amplifier stage is disclosed. The power amplifier stage comprises a power amplifier cell. The power amplifier stage also comprises a voltage detection circuit coupled to an output of the power amplifier cell. The power amplifier stage also comprises an over voltage protection (OVP) circuit coupled to the voltage detection circuit. The power amplifier stage also comprises a switch configured to short the power amplifier cell to ground based on a signal from the OVP circuit.

In another aspect, a method of protecting a power amplifier stage from an over voltage condition is disclosed. The method comprises detecting a voltage at an output of a power amplifier cell. The method also comprises, when the voltage at the output of the power amplifier cell exceeds a threshold, closing a switch such that the power amplifier cell is shorted to ground.

In another aspect, a mobile terminal is disclosed. The mobile terminal comprises a power amplifier stage. The power amplifier stage comprises a power amplifier cell. The power amplifier stage also comprises a voltage detection circuit coupled to an output of the power amplifier cell. The power amplifier stage also comprises an OVP circuit coupled to the voltage detection circuit. The power amplifier stage also comprises a switch configured to short the power amplifier cell to ground based on a signal from the OVP circuit.

### BRIEF DESCRIPTION OF THE DRAWINGS

FIG. 1 is a circuit diagram of a power amplifier stage with a conventional over voltage protection (OVP) circuit;

FIG. 2A is a circuit diagram of a single-ended power amplifier stage with an OVP circuit according to exemplary aspects of the present disclosure;

FIG. 2B is a circuit diagram of a differential-ended power amplifier stage with an OVP circuit according to exemplary aspects of the present disclosure;

FIG. 3 is a hybrid circuit and block diagram of an OVP circuit;

FIG. 4 is a flowchart illustrating an exemplary process for using the OVP circuit of the present disclosure;

FIG. 5 is a block diagram of a mobile terminal, which may include the OVP circuit of FIGS. 2A-3 and 6 according to the present disclosure;

FIG. 6 is a block diagram showing how a protection circuit may be provided for switches used to provide OVP for the power amplifier stage.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include systems and methods for providing a protection loop for a power amplifier. In particular, exemplary aspects of the present disclosure detect an over voltage condition at an output of a power amplifier and selectively create a short circuit at a base or gate of a transistor within the power amplifier to debias the transistor and prevent an over voltage condition from damaging the transistor. Provision of such a fast acting over voltage protection option more readily accommodates and protects the power amplifier in situations with high peak-to-average ratio conditions. This protection may prevent the transistor from being damaged by rapid power fluctuations that may occur, particularly in current cellular standards.

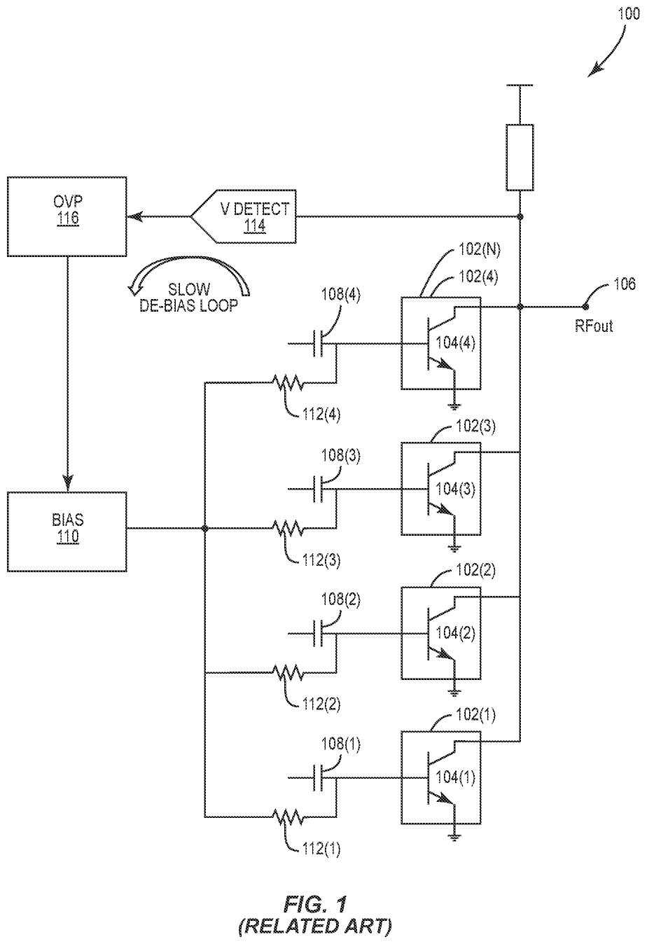

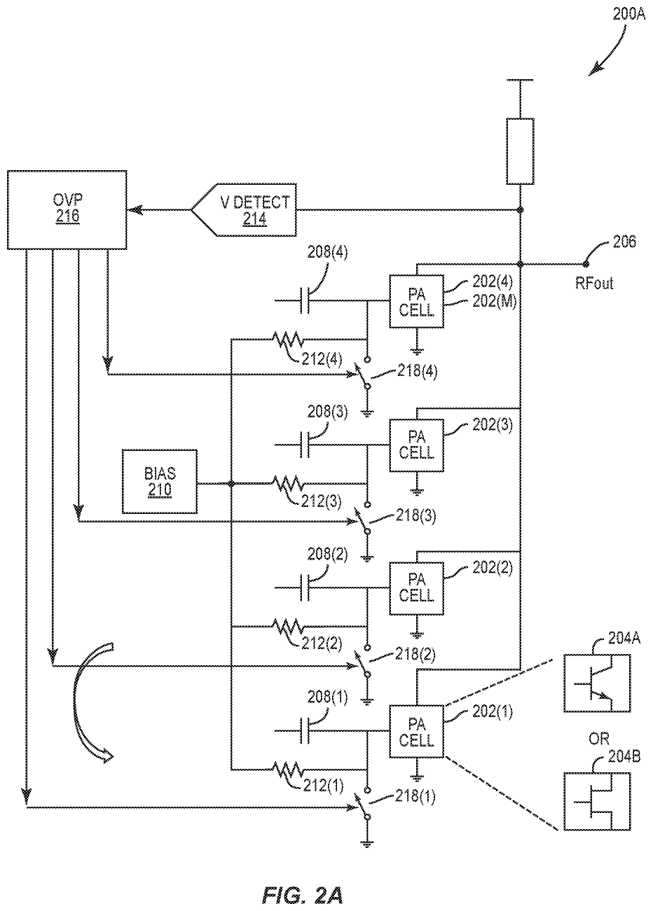

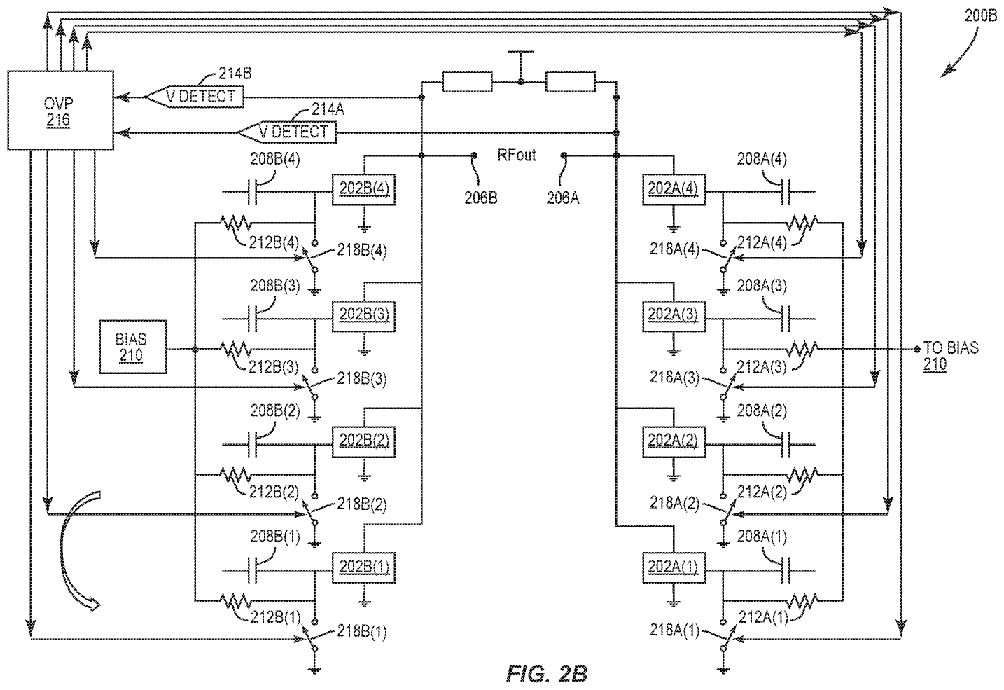

Before addressing exemplary aspects of the present disclosure, a brief discussion of the shortcomings of existing over voltage protection (OVP) circuits is provided, referring to FIG. 1. A discussion of exemplary aspects of the present disclosure begins below with reference to FIG. 2A.

In this regard, FIG. 1 is a circuit diagram of a power amplifier stage 100 that may have a plurality of parallel power amplifier cells 102(1)-102 (N), where N=4 for the purposes of example. As illustrated, each power amplifier cell 102(1)-102 (N) may include a respective transistor 104(1)-104(N). The respective collectors (not labeled) of the transistors 104(1)-104(N) may be coupled to a radio frequency (RF) output 106. Incoming signals to be amplified may pass through respective alternating current (AC) blocking capacitors 108(1)-108(N). A bias circuit 110 may provide a bias at respective bases (not labeled) of the transistors 104(1)-104(N) through respective ballast resistors 112(1)-112(N). A voltage detector circuit 114 may detect the voltage at the RF output 106 and provide an indication of voltage conditions to an OVP circuit 116. The OVP circuit 116 may provide a control signal to the bias circuit 110 to debias the power amplifier cells 102(1)-102(N) when an over voltage condition exists.

The inclusion of the bias circuit 110 in the OVP scheme results in a relatively slow debiasing of the transistors 104(1)-104(N) as the bias circuit 110 may have a relatively long time constant or otherwise impose delays. While effective for many types of over voltage protection, the advent of newer cellular standards opens up the possibility that there may be fast, large peak powers that do not change the average power much but do impose short-term transient stresses on the transistors 104(1)-104(N). When these peak powers are too high, the transistors 104(1)-104(N) may be damaged before the transistors 104(1)-104(N) may be debiased.

Exemplary aspects of the present disclosure provide a much faster debiasing solution, which will allow fast moving peak powers to be avoided and thereby avoid damage to transistors within the power amplifier cells. More specifically, exemplary aspects of the present disclosure contemplate a distributed shunt to ground being associated with inputs of the power amplifier cells.

In this regard, FIG. 2A illustrates a power amplifier stage 200A according to an exemplary aspect of the present disclosure. The power amplifier stage 200A is a single-ended power amplifier stage and may have a plurality of parallel power amplifier cells 202(1)-202(M), where M=4 for the purposes of example. It should be appreciated that each power amplifier cell 202(1)-202(M) may include a transistor. In exemplary aspects, the transistors may be bipolar junction transistors (BJTs) 204A or field effect transistors (FETs) 204B. The respective power amplifier cells 202(1)-202(M) may be coupled to an RF output 206. Incoming signals to be amplified may pass through respective AC blocking capacitors 208(1)-208(M). A bias circuit 210 may provide a bias for the power amplifier cells 202(1)-202(M) through respective ballast resistors 212(1)-212(M). A voltage detector circuit 214 may detect the voltage at the RF output 206 and provide an indication of voltage conditions to an OVP circuit 216. The OVP circuit 216 may provide a control signal to switches 218(1)-218(M).

The voltage detection by the voltage detector circuit 214 is relatively fast. Likewise, the activity in the OVP circuit 216 is relatively fast. Thus, most of the delay in previous OVP circuits was in the bias circuit 110. By not passing through the bias circuit 110, the switches 218(1)-218(M) may be opened and closed much quicker, and if the switches 218(1)-218(M) are also fast, then a short circuit to ground may be formed much faster than debiasing through the bias circuit 110 or 210. This short circuit to ground at a base of a BJT or a gate of a FET effectively turns off the transistors in the power amplifier cells 202(1)-202(M) and protects the transistors. While it possible to address the switches 218(1)-218(M) individually, it is also possible to open them all concurrently.

While the power amplifier stage 200A is single ended, the present disclosure is not so limited. A differential power amplifier stage 200B is illustrated in FIG. 2B. The power amplifier stage 200B may have a plurality of parallel power amplifier cells 202A(1)-202A(M) and 202B(1)-202B(M), where M=4 for the purposes of example. It should be appreciated that each power amplifier cell 202A(1)-202A(M) and 202B(1)-202B(M) may include a transistor such as a BJT or a FET. The respective power amplifier cells 202A(1)-202A(M) and 202B(1)-202B(M) may be coupled to RF outputs 206A, 206B. Incoming signals to be amplified may pass through respective AC blocking capacitors 208A(1)-208A(M) and 208B(1)-208B(M). A bias circuit 210 may provide a bias for the power amplifier cells 202B(1)-202B(M) through respective ballast resistors 212A(1)-212A(M) and 212B(1)-212B(M). Voltage detector circuits 214A, 214B may detect the voltage at the RF outputs 206A, 206B and provide an indication of voltage conditions to an OVP circuit 216. The OVP circuit 216 may provide a control signal to switches 218A(1)-218A(M) and 218B(1)-218B(M). In other regards, operation is substantially the same as the power amplifier stage 200A of FIG. 2A.

While single-ended and differential power amplifier stages have been explicitly disclosed and illustrated, it should be appreciated that the present disclosure may likewise be extended to quadrature power amplifier stages, Doherty power amplifiers, and any other load-modulated power amplifiers.

It should be appreciated that the switches 218 may also be transistors and may,

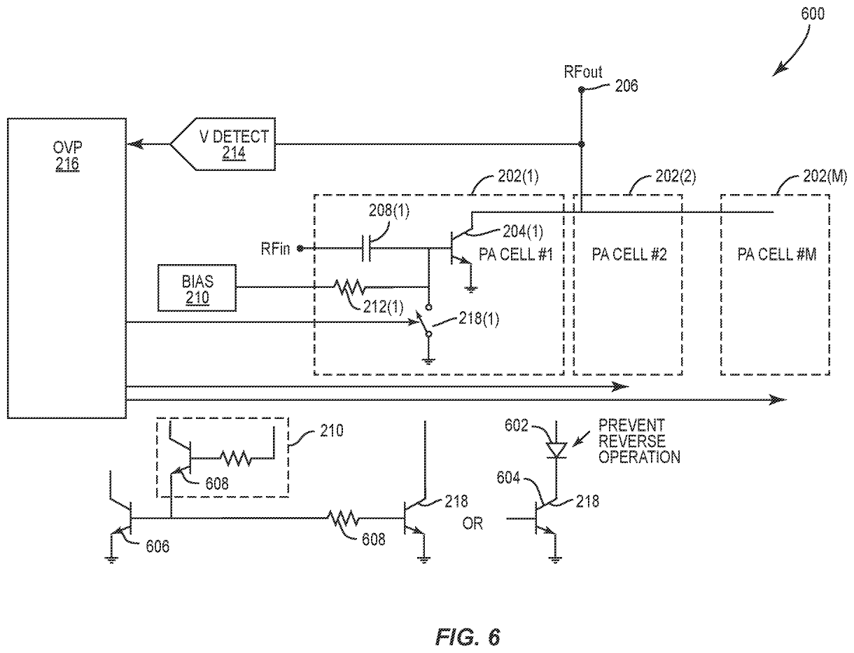

for example, be a BJT. The switches may be exposed to a large RF signal at the collector of the switch. If the RF signal at the collector goes negative, it is possible that the switch may conduct in an inversion mode, which is undesirable. To prevent such undesirable operation, protection may be provided to the switch, as better illustrated by a power amplifier stage 600 in FIG. 6. In particular, a diode 602 may be positioned in series between the collector 604 of the switch 218 and the power amplifier cell 202. The diode 602 allows current in only one direction, so the switch 218 would not operate in the inversion mode. Alternatively, because the diode 602 in series with the switch 218 introduces some voltage drop between the power amplifier cell 202 and ground (which may be sub-optimal for protecting the power amplifier cell), a diode 606 may be positioned with the bias circuit 210 (e.g., in series with an internal bias transistor 608) such that the switch 218 is always biased to prevent operation in the inversion mode.

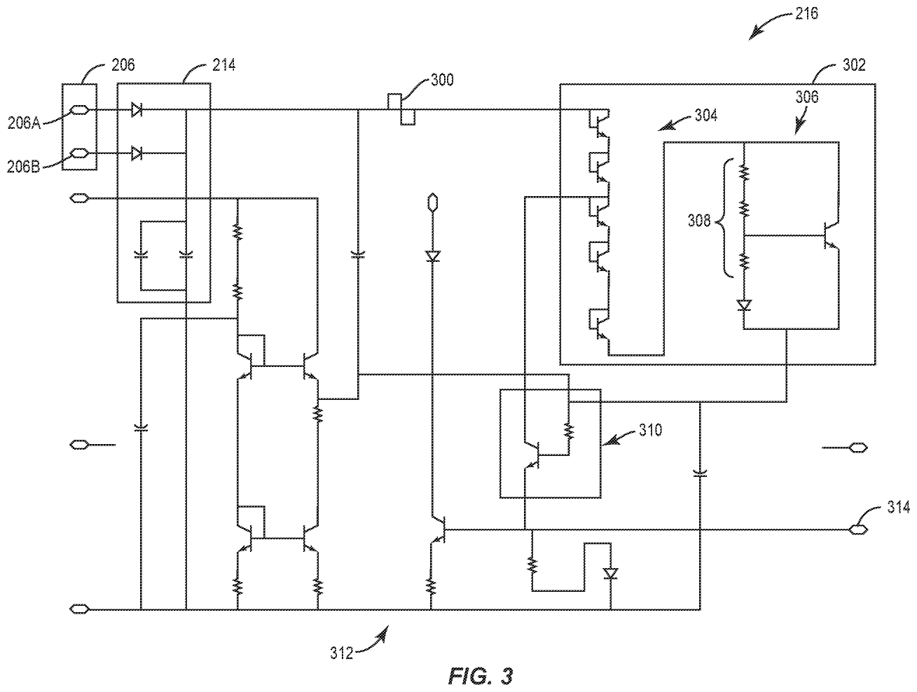

FIG. 3 shows more detail about a possible configuration of the OVP circuit 216. In particular, the OVP circuit 216 may be coupled to the output 206 (and as shown, is coupled to the differential output 206A, 206B). A voltage detector circuit 214 may be formed from diodes and capacitors to generate a detected voltage signal 300, which includes information about a voltage level. This signal 300 is then compared to a threshold. More specifically, a threshold level is subtracted from the detected voltage signal 300 in a threshold circuit 302. The threshold circuit 302 includes a coarse value formed by a plurality of transistors 304 operating as diodes and a fine value formed from a transistor 306 with a resistor network 308. That is, diodes are fairly coarse in terms of how much value they add to the total threshold. To tune that value, the resistor network 308 coupled to the transistor 306 adds a fraction of the value of the transistor 306 to the threshold. When the detected voltage signal 300 is high enough to turn on all the plurality of transistors 304 and the transistor 306, an over voltage condition is present. This over voltage condition is detected using, for example, current mode operation and, in particular, may use a Darlington current mirror 310, which needs low current levels to activate. Additional circuitry 312 may be present, but when the current mirror 310 provides a signal at node 314, this signal may be used to control the switches 218. Note that there are many other ways to implement an over voltage circuit.

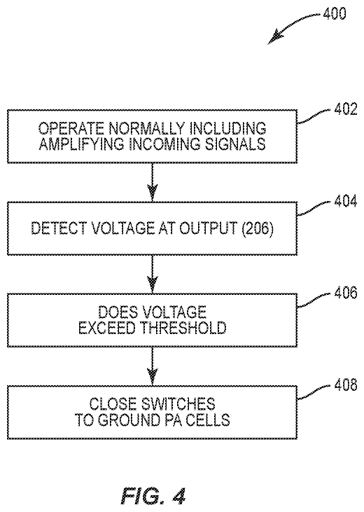

FIG. 4 provides a flowchart for a process 400 associated with operation of the power amplifier stages of the present disclosure. Specifically, the process 400 begins during normal operation and includes amplifying incoming signals (block 402). The voltage detector circuit 214 detects a voltage at the output 206 (block 404) and provides information about the detected voltage to the OVP circuit 216. The OVP circuit 216 determines if the voltage exceeds a threshold (block 406) and closes the switches 218(1)-218(M) to ground the power amplifier cells 202(1)-202(M) (block 408).

It should be appreciated that the power amplifier stages of the present disclosure are well suited for incorporation into a mobile computing device or mobile terminal or other device capable of wireless communication. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

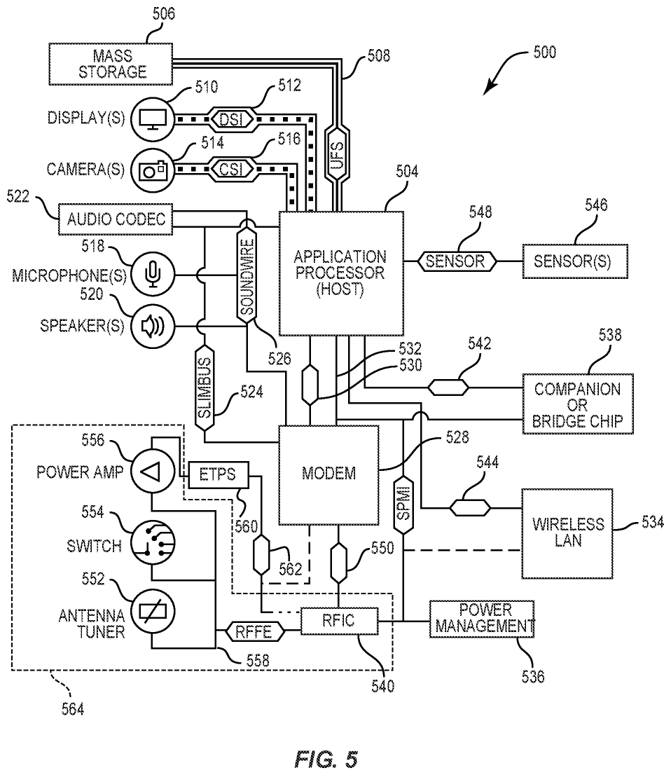

In this regard, FIG. 5 is a system-level block diagram of an exemplary mobile terminal 500. The mobile terminal 500 includes an application processor 504 (sometimes referred to as a host) that communicates with a mass storage element 506 through a universal flash storage (UFS) bus 508. The application processor 504 may further be connected to a display 510 through a display serial interface (DSI) bus 512 and a camera 514 through a camera serial interface (CSI) bus 516. Various audio elements such as a microphone 518, a speaker 520, and an audio codec 522 may be coupled to the application processor 504 through a serial low-power interchip multimedia bus (SLIMbus) 524. Additionally, the audio elements may communicate with each other through a SOUNDWIRE bus 526. A modem 528 may also be coupled to the SLIMbus 524 and/or the SOUNDWIRE bus 526. The modem 528 may further be connected to the application processor 504 through a peripheral component interconnect (PCI) or PCI express (PCIe) bus 530 and/or a system power management interface (SPMI) bus 532.

With continued reference to FIG. 5, the SPMI bus 532 may also be coupled to a local area network (LAN or WLAN) IC (LAN IC or WLAN IC) 534, a power management integrated circuit (PMIC) 536, a companion IC (sometimes referred to as a bridge chip) 538, and a radio frequency IC (RFIC) 540. It should be appreciated that separate PCI buses 542 and 544 may also couple the application processor 504 to the companion IC 538 and the WLAN IC 534. The application processor 504 may further be connected to sensors 546 through a sensor bus 548. The modem 528 and the RFIC 540 may communicate using a bus 550.

With continued reference to FIG. 5, the RFIC 540 may couple to one or more RFFE elements, such as an antenna tuner 552, a switch 554, and a power amplifier 556 through a radio frequency front end (RFFE) bus 558. Additionally, the RFIC 540 may couple to an envelope tracking power supply (ETPS) 560 through a bus 562, and the ETPS 560 may communicate with the power amplifier 556. Collectively, the RFFE elements, including the RFIC 540, may be considered an RFFE system 564. It should be appreciated that the RFFE bus 558 may be formed from a clock line and a data line (not illustrated). Power amplifier stages of the present disclosure may be found in the power amplifier 556 or other transceiver within the mobile terminal 500 (e.g., a WIFI, BLUETOOTH, or similar transceiver).

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

1. A power amplifier stage comprising:
a plurality of power amplifier cells;
a voltage detection circuit coupled to an output of the plurality of power amplifier cells;
an over voltage protection (OVP) circuit coupled to the voltage detection circuit; and
a plurality of switches, each of the plurality of switches corresponding to a respective one of the plurality of power amplifier cells, each of the plurality of switches capable of being addressed individually by the OVP circuit and configured to short the respective one of the plurality of power amplifier cells to ground based on a signal from the OVP circuit.

2. (canceled)

3. The power amplifier stage of claim 1, wherein the output comprises a single-ended output.

4. The power amplifier stage of claim 1, wherein the output comprises a differential output.

5. The power amplifier stage of claim 1, wherein the power amplifier cell comprises a bipolar junction transistor (BJT).

6. The power amplifier stage of claim 1, wherein the power amplifier cell comprises a field effect transistor (FET).

7. The power amplifier stage of claim 1, wherein the switch comprises a transistor.

8. The power amplifier stage of claim 1, further comprising a bias circuit coupled to the switch through a ballast resistor.

9. The power amplifier stage of claim 1, wherein the OVP circuit comprises a Darlington current mirror.

10. A method of protecting a power amplifier stage from an over voltage condition, the method comprising the steps of:
detecting a voltage at a common output of a plurality of power amplifier cells; and
when the voltage at the common output exceeds a threshold, closing one or more switches, where each switch is coupled to a respective one of the plurality of power amplifier cells and each switch is configured to short the respective one of the plurality of power amplifier cells to ground.

11. The method of claim 10, wherein detecting the voltage comprises detecting the voltage of a plurality of power amplifier cells.

12. The method of claim 10, further comprising comparing the voltage at the output to the threshold in an over voltage protection (OVP) circuit.

13. The method of claim 10, wherein detecting comprises detecting with a diode and a capacitor.

14. The method of claim 10, wherein closing the switch comprises using a transistor as the switch.

15. The method of claim 10, further comprising biasing the power amplifier cell.

16. A mobile terminal comprising:
a power amplifier stage comprising:
a plurality of power amplifier cells;
a voltage detection circuit coupled to an output of the plurality of power amplifier cells;
an over voltage protection (OVP) circuit coupled to the voltage detection circuit; and
a plurality of switches, each of the plurality of switches corresponding to a respective one of the plurality of power amplifier cells, each of the plurality of switches capable of being addressed individually by the OVP circuit and configured to short the respective one of the plurality of power amplifier cells to ground based on a signal from the OVP circuit.

17. (canceled)

18. The mobile terminal of claim 16, wherein the output comprises a single-ended output.

19. The mobile terminal of claim 16, wherein the output comprises a differential output.
